(19) United States
(12) Patent Application Publication
(10) Pub. No.: US 2024/0397664 A1
(43) Pub. Date: Nov. 28, 2024

(54) LIQUID COOLING SYSTEM HAVING LIQUID COOLING BLOCK COORDINATING WITH BUBBLE COOLING LIQUID

(71) Applicant: Long Victory Instruments Co., Ltd., Taoyuan City (TW)

(72) Inventor: CHIEN-CHUNG FENG, Taoyuan City (TW)

(21) Appl. No.: 18/674,374

(22) Filed: May 24, 2024

(30) Foreign Application Priority Data
May 25, 2023 (TW) 112119537

(51) Int. Cl. H05K 7/20; F28F 13/02

(52) U.S. Cl. CPC H05K 7/20272; F28F 13/02

(57) ABSTRACT

A liquid cooling system having a liquid cooling block coordinating with a bubble cooling liquid includes: a liquid cooling block having a channel, a liquid inlet, a liquid outlet and an adhesive surface; a bubble liquid source having a driving function for driving a liquid, connected to the liquid inlet by an incoming liquid pipe and adapted to provide a bubble cooling liquid; and a liquid storage tank connected to the liquid outlet by an outgoing liquid pipe, adapted to store the bubble cooling liquid, and connected to the bubble liquid source by a communication pipe. The size of the bubbles introduced by the bubble liquid source into the liquid ranges from 50 to 1000 nm. The bubble cooling liquid is a known material that does not boil in a normal working state and thus does not generate additional bubbles otherwise typical of boiling.

### BACKGROUND OF THE INVENTION

### 1. Field of the Invention

The present disclosure relates to heat dissipation technology using a liquid, and more particularly to a liquid cooling system having a liquid cooling block coordinating with a bubble cooling liquid.

### 2. Description of Related Art

China's patent 115235276A discloses an actively- and passively-aided phase-transition cooling device based on microbubble arrays and cascade grid walls, dissipating heat from a target object through latent heat with a phase-transition mechanism for generating bubbles by heating up a liquid until the liquid boils. The patent entails forming cascaded grid walls from cascaded micro-cylinder arrays and thus forming multiple gaps to provide a large number of micro-spaces for assisting with bubble formation and heat exchange during boiling.

China's patent 110534490A discloses a microstructure having a gradient in vertical direction in enhancing boiling and heat exchange and a method of manufacturing the same, dissipating heat from a target object through latent heat with a phase-transition mechanism for generating bubbles by heating up a liquid until the liquid boils. The microstructure has a heat spreader on which multiple micro-cylinders each having a square cross section are disposed. The micro-cylinders differ in height, with the central ones higher than the peripheral ones, and thus bubbles generated during a boiling process are unlikely to merge in the horizontal direction to otherwise create bigger bubbles.

The key technical feature of the aforesaid patents involves a mechanism for generating bubbles through the boiling of a liquid. However, the size of the bubbles thus generated is difficult to control. Furthermore, it is still possible for the bubbles thus generated to merge to create bigger bubbles. The problem of bubble merging remains unsolved despite a structural design aimed at mitigating bubble merging. Big bubbles are unlikely to enter corners inside a channel or gaps between fins disposed inside a channel, and thus the liquid is unlikely to enter corners inside the channel or gaps between fins disposed inside the channel. As a result, not only is the removal of the liquid impossible, but the flow of the liquid is also hindered, reducing the efficiency of heat dissipation or cooling.

Therefore, the prior art has a drawback in terms of generating bubbles in a liquid by boiling the liquid and thus still has room for improvement.

### BRIEF SUMMARY OF THE INVENTION

It is an objective of the disclosure to provide a liquid cooling system having a liquid cooling block coordinating with a bubble cooling liquid, characterized in that the bubble cooling liquid entering the liquid cooling block contains tiny bubbles that do not merge to create bigger bubbles but can entirely enter every corner inside a channel, conducive to destruction or reduction of a thermal boundary layer, enhancing heat dissipation or cooling.

To achieve the above and other objectives, the disclosure provides a liquid cooling system having a liquid cooling block coordinating with a bubble cooling liquid, comprising: a liquid cooling block having therein a channel for a bubble cooling liquid to pass through, the liquid cooling block having a liquid inlet and a liquid outlet in communication with two ends of the channel respectively, the bubble cooling liquid entering the liquid inlet, passing through the channel, and leaving the liquid outlet, the liquid cooling block having an adhesive surface for adhering to a heat source, wherein at least a portion of the channel is disposed in the liquid cooling block and corresponds in position to the adhesive surface; a bubble liquid source having a driving function for driving a liquid, connected to the liquid inlet by an incoming liquid pipe and adapted to introduce bubbles into a liquid to form the bubble cooling liquid, the bubble cooling liquid being outputted under a predetermined pressure and flowing into the liquid inlet via the incoming liquid pipe; and a liquid storage tank connected to the liquid outlet by an outgoing liquid pipe and adapted to admit and store the bubble cooling liquid having exited the liquid outlet, the liquid storage tank being connected to the bubble liquid source by a communication pipe, the bubble liquid source taking the liquid from the liquid storage tank, wherein the size of the bubbles introduced by the bubble liquid source into the liquid ranges from 50 to 1000 nm, wherein the bubble cooling liquid is a known material that does not boil in a normal working state and thus does not generate additional bubbles otherwise typical of boiling.

Therefore, the disclosure is characterized in that a bubble cooling liquid entering a channel of a liquid cooling block contains tiny bubbles that do not merge to create bigger bubbles but can entirely enter every corner inside the channel to enhance heat dissipation or cooling.

### BRIEF DESCRIPTION OF THE SEVERAL VIEWS OF THE DRAWINGS

FIG. 1 is a perspective view of a liquid cooling block according to a preferred embodiment of the disclosure.

FIG. 2 is an exploded view of the liquid cooling block according to a preferred embodiment of the disclosure.

FIG. 3 is a cross-sectional view taken along line 3-3 in FIG. 1.

FIG. 4 is a cross-sectional view taken along line 4-4 in FIG. 1.

FIG. 5 is a schematic view of the inside of the liquid cooling block similar to that of FIG. 4.

FIG. 6 is another schematic view of the inside of the liquid cooling block similar to that of FIG. 4.

FIG. 7 is a block diagram of a preferred embodiment of the disclosure.

FIG. 8 is a schematic view of how to use a preferred embodiment of the disclosure.

FIG. 9 is another schematic view of how to use a preferred embodiment of the disclosure.

### BRIEF DESCRIPTION OF THE SEVERAL VIEWS OF THE DRAWINGS

Technical features of the disclosure are herein illustrated with preferred embodiments, depicted with drawings, and described below.

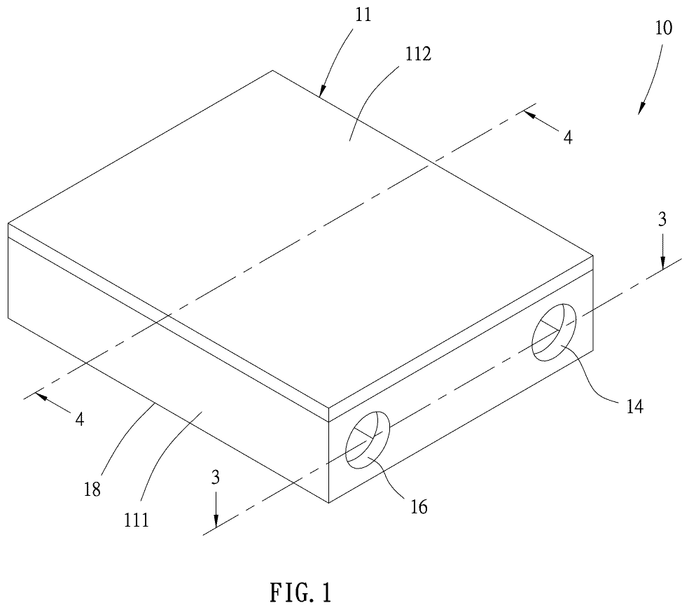

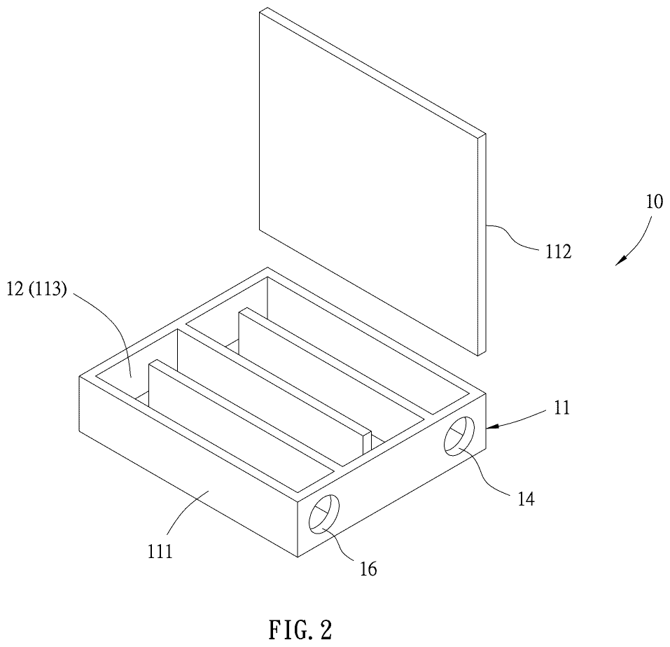

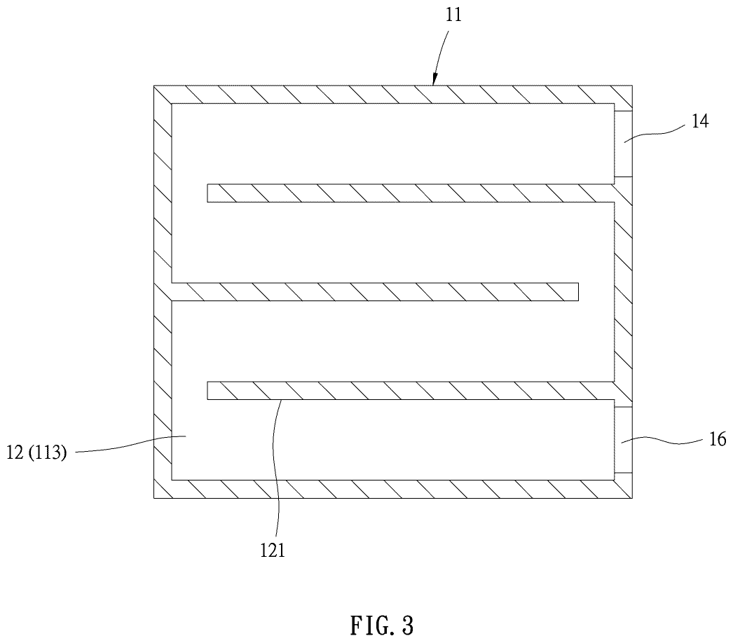

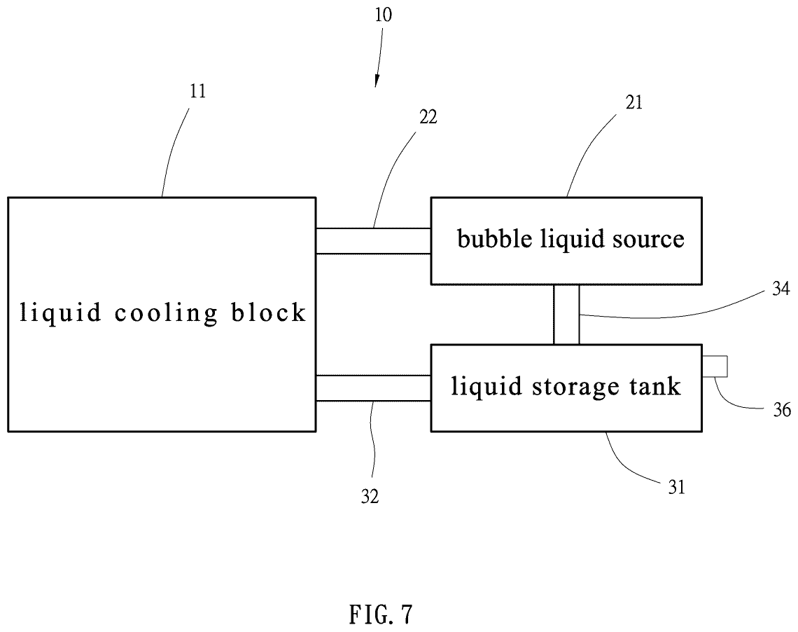

Referring to FIG. 1 through FIG. 8, a preferred embodiment of the disclosure discloses a liquid cooling system 10 comprising a liquid cooling block coordinating with a bubble cooling liquid, essentially comprising a liquid cooling block 11, a bubble liquid source 21 and a liquid storage tank 31.

The liquid cooling block 11 has therein a channel 12 for a bubble cooling liquid 91 to pass through. The liquid cooling block 11 has a liquid inlet 14 and a liquid outlet 16 which are in communication with two ends of the channel 12 respectively. The bubble cooling liquid 91 enters the liquid inlet 14, passes through the channel 12, and leaves the liquid outlet 16. The liquid cooling block 11 has an adhesive surface 18 that adheres to a heat source 99. At least a portion of the channel 12 is disposed in the liquid cooling block 11 and corresponds in position to the adhesive surface 18. In this embodiment, the liquid cooling block 11 has a body 111 and a lid 112 for covering the body 111. A groove 113 that opens outward is concavely disposed at the body 111. After covering the body 111, the lid 112 covers the groove 113 to form the channel 12. The channel 12 disposed in the liquid cooling block 11 is crooked.

The bubble liquid source 21 has a driving function for driving a liquid and is connected to the liquid inlet 14 by an incoming liquid pipe 22 and adapted to introduce bubbles into a liquid 92 to form the bubble cooling liquid 91. Then, the bubble cooling liquid 91 is outputted under a predetermined pressure and flows into the liquid inlet 14 via the incoming liquid pipe 22. The predetermined pressure is greater than normal pressure, normally 2˜3 atms. The bubble liquid source 21 itself can be a water pump for driving a liquid. The bubbles are so tiny that they are depicted by a plurality of black dots without any reference numeral in the accompanying drawings.

The liquid storage tank 31 is connected to the liquid outlet 16 by an outgoing liquid pipe 32 and adapted to admit and store the bubble cooling liquid 91 which has exited the liquid outlet 16. The liquid storage tank 31 is connected to the bubble liquid source 21 by a communication pipe 34. The bubble liquid source 21 takes the liquid 92 from the liquid storage tank 31 via the communication pipe 34. The bubble cooling liquid 91, which exits the liquid outlet 16 and enters the liquid storage tank 31, contains bubbles; thus, the liquid storage tank 31 has a bubble removal mechanism, for example, a container with a large capacity, leaving most of the liquid 92 to stand so as for the bubbles to be removed gradually. Alternatively, the bubble removal mechanism in this embodiment is, for example, a vent 36 for gas discharge. Since a gas discharge mechanism is a well-known technology in the technical field of liquid cooling, the vent 36 is schematically depicted in the accompanying drawings without going into detail.

The size of the bubbles introduced by the bubble liquid source 21 into the liquid 92 ranges from 50 to 1000 nm, and is, for example, 150 nm in this embodiment. The bubble cooling liquid 91 is a known material, for example, water, ethylene glycol aqueous solution or propylene glycol aqueous solution. Therefore, the bubble cooling liquid 91 does not boil in a normal working state and thus does not generate additional bubbles otherwise typical of boiling. To this end, considerations must be given to the power of the heat source 99 which the liquid cooling block 11 adheres to. Take water as an example, its boiling point is 100° C. If the heat source 99 which the liquid cooling block 11 adheres to is a conventional CPU for computers, the working temperature will be around 70° C., preventing boiling from occurring in the working state and additional bubbles from arising. In practice, boiling and generation of bubbles will not occur, provided that the temperature of the bubble cooling liquid 91 discharged from the liquid outlet 16 is at least 10° C. lower than its boiling point.

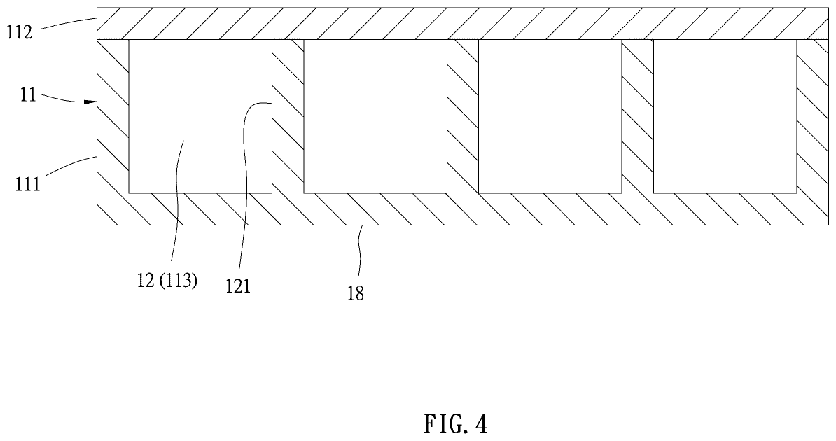

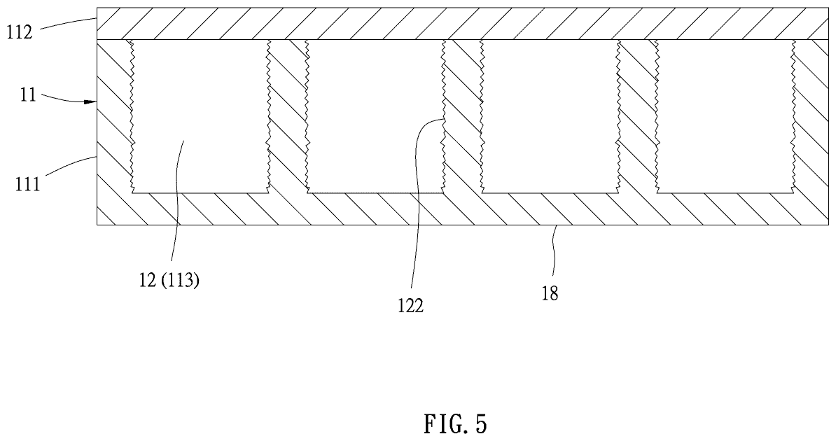

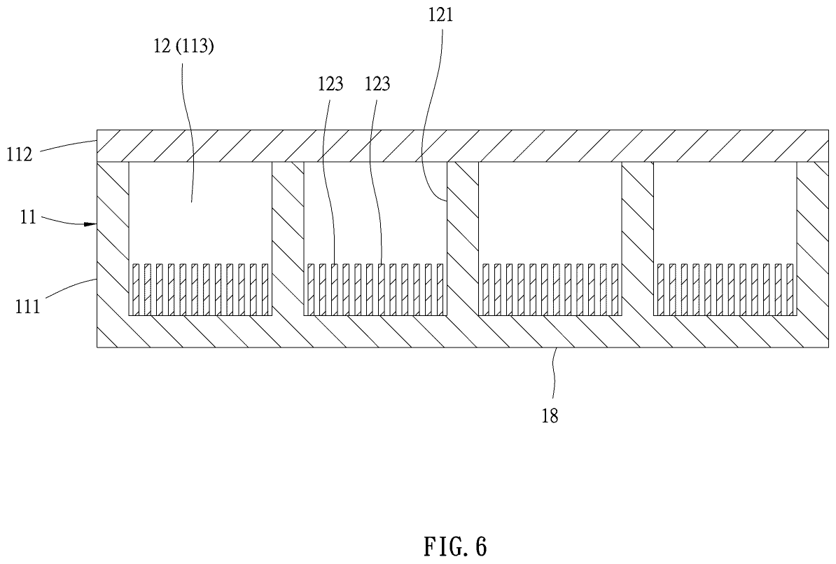

As shown in FIG. 4, the peripheral wall of the channel 12 is defined as a channel surface 121, and the channel surface 121 does not have any additional raised structure, dented structure or rough capillary structure. In short, the channel surface 121 is a smooth surface or a structure that did not undergo surface polishing treatment. As shown in FIG. 5, the channel surface 121 has an additional rough capillary structure 122, for example, a surface that was etched with chemicals and thus is rough or a surface that underwent sandblasting. As shown in FIG. 6, the channel surface 121 has a plurality of fins 123 which have a predetermined height, extend by a predetermined length in the direction of extension of the channel 12, and are parallel. The distance between any two adjacent ones of the fins 123 is greater than the size of the bubbles in the bubble cooling liquid 91.

The structural features of this embodiment are described above. The operation state of this embodiment is described below.

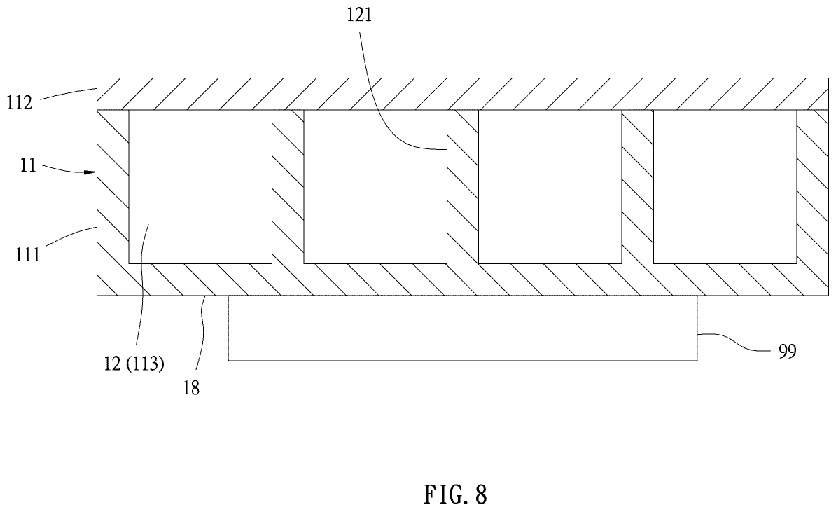

As shown in FIG. 8, before operation, the adhesive surface 18 of the liquid cooling block 11 adheres to the heat source 99.

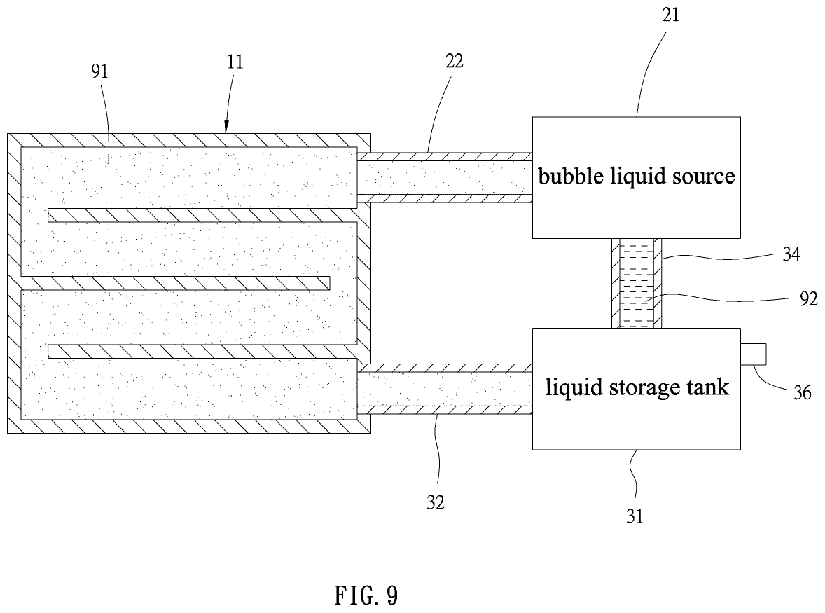

As shown in FIG. 9, during operation, the bubble liquid source 21 provides the bubble cooling liquid 91 which exits the incoming liquid pipe 22, enters the channel 12 via the liquid inlet 14, passes through the channel 12 before being discharged from the liquid outlet 16, and flows into the liquid storage tank 31 via the outgoing liquid pipe 32. In the liquid storage tank 31, the bubble cooling liquid 91 undergoes removal of bubbles and thus becomes the liquid 92. Alternatively, the need to remove bubbles can be dispensed with, and the bubble liquid source 21 takes the liquid 92, pressurizes the liquid 92, introduces bubbles into the liquid 92, and drives the liquid 92 into the incoming liquid pipe 22. The aforesaid cycle continues endlessly, the liquid cooling block 11 is effective in enhancing heat dissipation or cooling through the bubble cooling liquid 91, as explained below.

The key mechanisms for enhancing heat dissipation or cooling according to the disclosure are described below. The bubbles in the bubble cooling liquid 91 are 50˜1000 nm in size, and thus the bubble cooling liquid 91 does not boil in the working state. Persons skilled in the art are aware that tiny bubbles or smaller bubbles are 50˜1000 nm in size and thus do not float but are suspended in a liquid. Persons skilled in the art are also aware that extremely tiny bubbles, for example, bubbles 50˜100 nm in size, intrinsically carry the same polarity (negative electric charges or positive electric charges) and thus repel each other, preventing the bubbles from merging to otherwise create bigger bubbles.

According to the disclosure, the bubble cooling liquid 91 which contains the aforesaid tiny bubbles promote the disturbance of a thermal boundary layer inside the channel 12 and hit the blind spots inside the channel 12 to promote the movement of the bubble cooling liquid 91 inside the channel 12, enhancing heat dissipation or cooling.

As shown in FIG. 9, the bubble cooling liquid 91 which contains the aforesaid tiny bubbles disturbs or hits the channel surface 121 and the blinds spots inside the channel 12 while passing through the channel 12. Referring to FIG. 5 and FIG. 6, the channel surface 121 has a rough capillary structure 122 or the plurality of fins 123, the aforesaid tiny bubbles can easily approach the surface of the capillary structure 122 or pass through the gap between any two adjacent ones of the fins 123 to disturb the bubble cooling liquid 91 near the surface of the capillary structure 122 or the bubble cooling liquid 91 between any two adjacent ones of the fins 123 to increase the fluidity in spots which are otherwise almost blind, enhancing heat dissipation.

Therefore, the disclosure is characterized in that a bubble cooling liquid entering a channel of a liquid cooling block contains tiny bubbles that do not merge to create bigger bubbles but can entirely enter every corner inside the channel or pass through the gap between any two adjacent ones of the fins to enhance heat dissipation or cooling.

What is claimed is:

1. A liquid cooling system having a liquid cooling block coordinating with a bubble cooling liquid, comprising:
a liquid cooling block having therein a channel for a bubble cooling liquid to pass through, the liquid cooling block having a liquid inlet and a liquid outlet in communication with two ends of the channel respectively, the bubble cooling liquid entering the liquid inlet, passing through the channel, and leaving the liquid outlet, the liquid cooling block having an adhesive surface for adhering to a heat source, wherein at least a portion of the channel is disposed in the liquid cooling block and corresponds in position to the adhesive surface;
a bubble liquid source having a driving function for driving a liquid, connected to the liquid inlet by an incoming liquid pipe and adapted to introduce bubbles into a liquid to form the bubble cooling liquid, the bubble cooling liquid being outputted under a predetermined pressure and flowing into the liquid inlet via the incoming liquid pipe; and
a liquid storage tank connected to the liquid outlet by an outgoing liquid pipe and adapted to admit and store the bubble cooling liquid having exited the liquid outlet, the liquid storage tank being connected to the bubble liquid source by a communication pipe, the bubble liquid source taking the liquid from the liquid storage tank,
wherein size of the bubbles introduced by the bubble liquid source into the liquid ranges from 50 to 1000 nm,
wherein the bubble cooling liquid is a known material that does not boil in a normal working state and thus does not generate additional bubbles otherwise typical of boiling.

2. The liquid cooling system having a liquid cooling block coordinating with a bubble cooling liquid according to claim 1, wherein the channel disposed in the liquid cooling block is crooked.

3. The liquid cooling system having a liquid cooling block coordinating with a bubble cooling liquid according to claim 1, wherein the predetermined pressure is greater than normal pressure.

4. The liquid cooling system having a liquid cooling block coordinating with a bubble cooling liquid according to claim 1, wherein the liquid cooling block has a body and a lid for covering the body, and a groove that opens outward is concavely disposed at the body, wherein, after covering the body, the lid covers the groove to form the channel.

5. The liquid cooling system having a liquid cooling block coordinating with a bubble cooling liquid according to claim 1, wherein a peripheral wall of the channel is defined as a channel surface that lacks any raised structure, dented structure or rough capillary structure.

6. The liquid cooling system having a liquid cooling block coordinating with a bubble cooling liquid according to claim 1, wherein a peripheral wall of the channel is defined as a channel surface that has a rough capillary structure.

7. The liquid cooling system having a liquid cooling block coordinating with a bubble cooling liquid according to claim 1, wherein a peripheral wall of the channel is defined as a channel surface having a plurality of fins being of a predetermined height, and the plurality of fins extend by the predetermined length in a direction of extension of the channel.

8. The liquid cooling system having a liquid cooling block coordinating with a bubble cooling liquid according to claim 7, wherein the plurality of fins are parallel, and a distance between any two adjacent ones of the fins is greater than the size of the bubbles in the bubble cooling liquid.

9. The liquid cooling system having a liquid cooling block coordinating with a bubble cooling liquid according to claim 1, wherein a temperature of the bubble cooling liquid discharged from the liquid outlet is at least 10° C. lower than its boiling point.

10. The liquid cooling system having a liquid cooling block coordinating with a bubble cooling liquid according to claim 1, wherein the liquid storage tank has a vent.
